(19) United States
(12) Patent Application Publication
(10) Pub. No.: US 2013/0176036 A1
(43) Pub. Date: Jul. 11, 2013

(54) FIELD DEVICE FOR DETERMINING AND/OR MONITORING A CHEMICAL OR PHYSICAL PROCESS VARIABLE IN AUTOMATION TECHNOLOGY

(71) Applicants: Roland Grozinger, Heitersheim (DE); Peter Klofer, Steinen (DE)

(72) Inventors: Roland Grozinger, Heitersheim (DE); Peter Klofer, Steinen (DE)

(73) Assignee: Endress + Hauser GmbH + Co. KG, Maulburg (DE)

(21) Appl. No.: 13/822,843

(22) PCT Filed: Aug. 31, 2011
(86) PCT No.: PCT/EP2011/064992

§ 371 Date: Mar. 13, 2013

(30) Foreign Application Priority Data
Sep. 16, 2010 (DE) 10 2010 040 866.2

(51) Int. Cl. G01R 27/26

(52) U.S. Cl. CPC G01R 27/2611
USPC 324/655

(57) ABSTRACT

A field device for determining and/or monitoring a chemical or physical, process variable in automation technology, which has at least a first electronic or electrical component and a second electronic or electrical component. The first component has an energy transmitting antenna and the second component has an energy receiving antenna. Between the two components a predetermined distance is provided, which sets the first component and the second component apart from one another. The predetermined distance is filled, at least partially, with a dielectric medium. The energy transmitting antenna is so embodied and/or arranged that it supplies the second component with energy continuously or at predetermined time intervals.

The invention relates to a field device for determining and/or monitoring a chemical or physical, process variable in automation technology, wherein the field device has at least a first electronic or electrical component and a second electronic or electrical component.

In automation technology, especially in process automation technology, field devices are often applied, which serve for registering and/or influencing process variables. Serving for registering process variables are sensors, such as, for example, fill level measuring devices, flow measuring devices, pressure- and temperature measuring devices, pH-redox potential measuring devices, conductivity measuring devices, etc., which register the corresponding process variables, fill level, flow, pressure, temperature, pH-value, and conductivity. Serving for influencing process variables are actuators, such as, for example, valves or pumps, via which the flow of a liquid in a section of pipeline or the fill level in a container can be changed. Referred to as field devices are, in principle, all devices, which are applied near to the process and deliver, or process, process relevant information. In connection with the invention, field devices thus include especially also remote I/Os, radio adapters, or, generally, devices, which are arranged at the field level. A large number of such field devices are produced and available from the firm, Endress+Hauser.

In modern process plants, communication between at least one superordinated control unit and the field devices occurs, as a rule, via a bus system, such as, for example, a Profibus® PA, Foundation Fieldbus® or HART® bus system. The bus systems can be embodied both using wires as well as also wirelessly. The superordinated control unit serves for process control, for process visualizing, for process monitoring as well as for start-up and servicing of the field devices and is also referred to as a configuration/management system. Programs, which run self-sufficiently on superordinated units, are operating, or servicing, tools. These include, for example, the FieldCare tool of the group of firms, Endress+Hauser, the Pactware tool, the AMS tool of Fisher-Rosemount or the PDM tool of Siemens. Such tools integrated in control system applications are to be found in the PCS7 system of Siemens, the Symphony system of ABB and the Delta V system of Emerson. The terminology ‘servicing field devices’ is meant to include, especially, the configuring and parametering of field devices, however, also diagnosis for the purpose of early detection of defects in the field devices or in the process.

Usually, individual components of field devices in automation technology are connected with one another via electrically conductive lines and are supplied with energy via such lines. Energy transmission via cable, respectively, via wire-based connecting lines, has disadvantages as follows:
Wired EMC (electromagnetic compatibility) disturbances travel via the cable, respectively the connecting line, directly to the individual components; and
in order, in the case of malfunction, to avoid the transmission of overvoltages between the components, the components must be protected by corresponding power limiting measures. These so-called Ex limiting measures have, however, the disadvantage that, in normal operation, they consume a large part of the already scarce power.

An object of the invention is to provide a field device that avoids these disadvantages.

The object is achieved by features including that the first component has an energy transmitting antenna, or transmitting coil, and the second component has an energy receiving antenna, or receiving coil, wherein there is between the two components a predetermined distance, which sets the first component and the second component apart from one another, wherein the distance is filled, at least partially, with a dielectric medium, wherein wireless energy transmission occurs over larger distances from an energy transmitting antenna to an energy receiving antenna by means of resonant oscillatory circuits of equal resonant frequency, and wherein the energy transmitting antenna is so embodied and/or arranged that it supplies the second component with energy continuously or at predetermined time intervals.

Especially advantageous is when the field device is so embodied that it is suitable for use in an explosion endangered area.

The above described disadvantages of a wired energy transmission are bypassed by the solution of the invention. Especially, the invention completely eliminates wire-based EMC disturbances. This is not completely possible with the known galvanic decoupling based e.g. on conventional transformers with core. In contrast, field devices of the invention have, as regards the power supply, complete EMC, as well as galvanic, isolation. This also facilitates and simplifies use in an explosion endangered area, since power consuming Ex limitings are not necessary. Furthermore, the invention has the advantage that the spatial isolation automatically also provides a climatic decoupling.

Preferably, WREL technology “Wireless Resonant Energy Link” technology is used as the basis for the energy transmitting antenna and the energy receiving antenna. Current intensive developmental work for this wireless energy transmission per resonance have actually the goal of transmitting over, in comparison to the here described dimensions, clearly greater distances and also clearly higher energies from an energy transmitting antenna, or transmitting coil, to an energy receiving antenna, or receiving coil. The fundamental principle of WREL technology rests on the principle of resonance: A WREL receiver can with a wire coil absorb energy from a magnetic field, when it is radiated with corresponding frequency from a transmitter via a wire coil. In such case, the WREL receiver determines by its embodiment exactly the desired electrical current level and voltage. By means of an inductive coupling of two resonant oscillatory circuits of an antenna capacitance and a coupling coil via a shared magnetic field, energy can be transmitted very efficiently. For this, the resonance frequencies of the resonant oscillatory circuits of the transmission antennas and the receiving antennas must be matched to one another. The resonance frequencies of the resonant oscillatory circuits lie in the mega-hertz region, in order to radiate as little energy as possible into the environment or to influence such environment as little as possible. Furthermore, the WREL transmitting antenna radiates always only as much energy as the receiving antenna is requesting. Within the operating range of the transmitting antenna, the position of the receiving antenna can be changed, without that the quality of the energy transmission suffers thereby. A similar technique of energy transmission is described, for example, in the publication, “Witricity-Drahtlose Energieübertragung (Witricity Wireless Energy Transmission)”; Rico Zanchetti & Luca Costa; HTW Chur, Switzerland.

An advantageous embodiment of the field device of the invention provides that the first component comprises an electronics/connector space embodied according to a first ignition protection type and that the second component comprises a sensor module, or actuator module, embodied according to a second ignition protection type. In such case, the sensor module, or actuator module, is spaced from the electronics/connector space by a dielectric spacer. This spacer serves also for thermal decoupling of electronics/connector space and sensor/actuator module. The sensor module, respectively the actuator module, includes, respectively, a sensor or an actuator. The energy transmitting antenna is associated with the electronics/connector space, while the energy receiving antenna is associated with the sensor module. The energy transmitting antenna supplies the sensor module, or the actuator module, wirelessly with energy. Examples of sensors and actuators are already sufficiently described above, so that repetition here is omitted. Based on mutually separated housing chambers, a complete climatic decoupling can be assured.

Alternatively, the second component can be a main board, which follows on a connector circuit board. Furthermore, the principle and advantage of the wireless energy transmission can also be applied between all circuit boards of a complex, total electronics. Of course, the dielectric material can also be air.

Another embodiment relates to the use of the solution of the invention for products of the E+H group, which use the Memosens technology. For the purpose of energy supply, here e.g. a transmitting antenna is associated with the sensor cable, while the receiving antenna is arranged in the sensor head.

In the case of an embodiment of a field device usual in automation technology, the electronics/connector space is embodied pressure resistantly, especially such that it qualifies for Ex d ignition protection, while the sensor module is embodied to be intrinsically safe, especially such that it qualifies for Ex i ignition protection. In order to assure Ex i safety, Ex barriers are usually provided, which so limit the power supply of the connector space for the sensor- or actuator module that, in the case of a defect, no spark formation occurs, which could lead to an explosion in the external space. Thus, the power supply is limited, and this usually results in a smaller measuring rate for the field device. Since, furthermore, power supply occurs via lines, these are subject to the already described wired EMC disturbances. These disadvantages are eliminated by the wireless energy transmission of the invention. Additionally, always only the power required by the second component, e.g the sensor- or actuator module, is transmitted. It suffices, thus, to so design the sensor module, or the actuator module, that it only withdraws from the energy transmitting antenna the maximum power allowable for an explosion endangered area.

A preferred embodiment of the field device of the invention provides that, supplementally, also communication between the electronics/connector space and the sensor module occurs with galvanic isolation, e.g. via radio or via fiber optics. This is already possible and usual today, since, in the case of pure data-communication, virtually no energy is transmitted.

Especially suitable for the invention is a field device in the form of a radar measuring device for determining the fill level of a fill substance in a container. In this case, there is arranged in the electronics/connector space a sensor electronics for processing/evaluating the measurement data delivered by the sensor element. Located in the sensor module itself is a high frequency module, which produces high-frequency measuring signals, especially microwaves. The high-frequency measuring signals are in the GHz region. Corresponding fill level measuring devices are available from the assignee in a number of different embodiments.

An embodiment of the field device of the invention provides that a plurality of second components are provided, which are supplied with energy simultaneously or one after the other via the energy transmitting antenna. In such case, the following manner of operation is brought to bear: The wireless energy transmission uses two or more, coupled resonance coils. One of the coils is the energy source, or the energy transmitter, while the other coil, or the other coils is/are the energy sink/the energy sinks, or the energy receiver/the energy receivers. The transmitting coil is preferably fed with a high-frequency, alternating voltage having a frequency in the order of magnitude of 10 MHz. Receiving coils, which are located at a suitable distance from the transmitting coil and have the matching resonant frequency, can receive energy from the transmitting coil. In such case, always that energy is transmitted, which is currently required by the receiver coil. In contrast, no energy is transmitted to receiving coils, whose resonant frequency does not match the transmission frequency of the transmitting coil.

An advantageous embodiment of the field device of the invention provides that a superordinated control unit is assigned to the field device and that communication between field device and superordinated control unit occurs via at least one connecting line matched to the respective explosion endangered area. Alternatively, the data transmission can also occur inductively, capacitively, optically or wirelessly. The superordinated control unit is a PLC, i.e. a programmable logic controller, or a PCS, i.e. a process control system. Corresponding examples have already been named above.

Furthermore, it is provided that the energy supply from the control unit likewise occurs wirelessly. For this, there must be provided in the first component, besides the energy transmitting antenna, also an energy receiving antenna. A corresponding solution is described in the patent application filed on the same day as the present application at the German Patent Office with the title “System mit zumindest einer Energie-Sendeantenne and zumindest einem Feldgerät (SYSTEM WITH AT LEAST ONE ENERGY TRANSMITTING ANTENNA AND AT LEAST ONE FIELD DEVICE, DE102010040865A1)”. The disclosure of such parallel patent application is herewith expressly incorporated into the present patent application, since the two can also work in combination.

In an advantageous embodiment of the field device of the invention, an energy storer is associated therewith for storing energy received by the energy receiving antenna. This has the advantage that, in the case of a short-term disturbance of the energy transmission, correct functioning of the field device is assured.

The invention will now be explained in greater detail based on the appended drawing, the sole figure of which shows as follows:

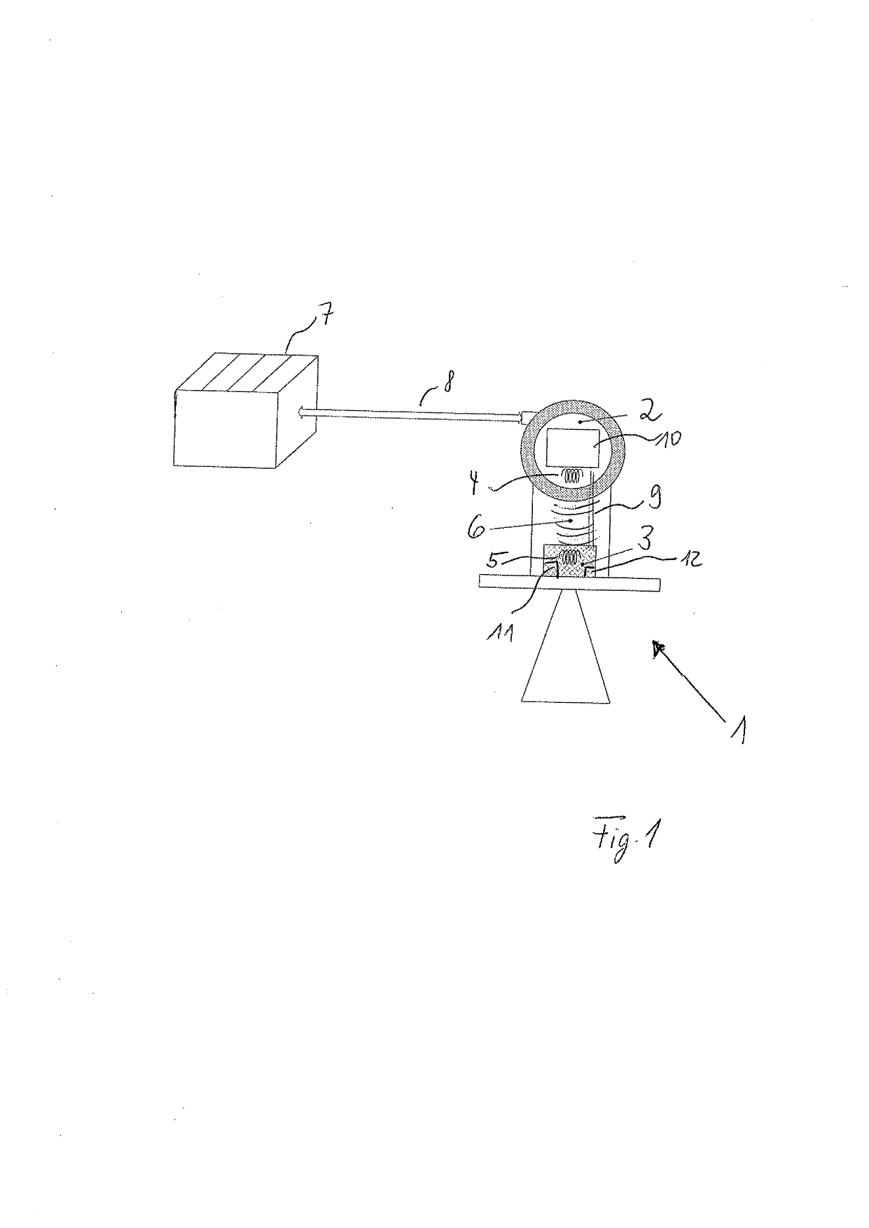

FIG. 1 a schematic view of a field device embodied in the form of a fill-level measuring device.

Fill-level measuring device 1 determines the fill level of a fill substance in a container via a travel-time method. Corresponding fill level measuring devices are known in the most varied of forms.

In general, the field device 1 of the invention serves, however, as already indicated above, for determining and/or monitoring a chemical or physical, process variable in the field of automation technology, especially in process automation technology.

A preferred subfield of use of the field device 1 is in an explosion endangered area. Field device 1 includes, as first component 2, an electronics/connector space and as second component 3, a sensor module. Electronics/connector space 2 contains a sensor electronics 10 for processing and evaluating measurement data delivered by the sensor. Located in the sensor module 3 is an HF module 11, which serves for producing high-frequency measurement signals. Also arranged in the electronics/connector space 2 is an energy transmitting antenna 4. The energy transmitting antenna 4 is so embodied and/or arranged that it supplies the second component 3 with energy continuously or at predetermined time intervals.

For this, an energy receiving antenna 5 is associated with the sensor module 3. Provided between the two components 2, 3 is a predetermined distance 6, which sets the first component 2 and the second component 3 apart from one another. This distance 6 is at least partially filled with a dielectric medium. Preferably, the dielectric material is a synthetic material (plastic), glass or ceramic. However, the dielectric material can also be simply air. A purpose of the distance 6, or of the spacer 6, is to decouple the two components 2, 3 thermally from one another. A typical distance between the electronics/connector space 2 and the sensor module amounts, in the case of fill-level measuring devices, to 5 mm to 20 cm.

In a preferred embodiment, the electronics/connector space 2 is embodied to be pressure resistant, especially such that it qualifies for Ex d ignition protection, while the sensor module 3 is embodied to be intrinsically safe, especially such that it qualifies for Ex i ignition protection.

Communication between electronics/connector space 2 and the sensor module 3 occurs either via radio or via a fiber optics connection 9. In principle, however, also capacitive, optical or inductive data transmission represent other options.

Of course, one energy transmitting antenna can also supply a number of different second components 3 with energy—also those of other field devices arranged in the vicinity.

Usually, field devices are connected with a superordinated control unit 7 via a bus system. In FIG. 1, thus, the system of the invention is not limited to one field device 1 and a superordinated control unit 7, but, instead, usually there are connected with the control unit 7 a plurality of equal or different field devices 1, which serve for control of a process installation. Communication between the at least one field device 1 and the superordinated control unit 7 occurs via at least one connecting line 8 adapted for the respective explosion endangered area. Suitable, known bus protocols are mentioned above.

For example, the connection can comprise a casing meeting increased safety requirements. Of course, communication can, however, also occur wirelessly. Likewise an option is to transmit the energy via the earlier described, e.g. WREL, technology from the superordinated control unit 7 to the field devices 1. A corresponding system is described in the parallel German patent application of equal filing date. The disclosure of this parallel patent application is incorporated by reference into the present patent application.

In order to assure that the field device remains operationally ready even in the case of a short-term failure of the power transmission, an energy storer 12 is provided, which stores the energy received by the energy receiving antenna 4 in the sensor module 3 and, when required, makes such stored energy available.

### LIST OF REFERENCE CHARACTERS

1 field device
2 connector space/first component
3 sensor module/actuator module/second component
4 energy transmitting antenna
5 energy receiving antenna
6 distance/spacer
7 superordinated control unit
8 connecting line
9 optical line
10 sensor electronics
11 HF module
12 energy storer

1-10. (canceled)

11. A field device for determining and/or monitoring a chemical or physical, process variable in automation technology, comprising:
at least a first electronic or electrical component space;
a second electronic or electrical component;
an energy transmitting antenna situated in said space;
an energy receiving antenna, associated with said second component; and
a predetermined distance, which sets the first component and the second component apart from one another, wherein:
said predetermined distance is filled, at least partially, with a dielectric medium;
wireless energy transmission occurs over larger distances from said predetermined distance means of resonant oscillatory circuits, the resonant oscillatory circuit of said receiving antenna and the resonant oscillatory circuit of said transmitting antenna are so embodied and arranged that the two have resonant frequencies which are equal to one another; and
said energy transmitting antenna is so embodied and/or arranged that it supplies said second component with energy continuously or at predetermined time intervals.

12. The field device as claimed in claim 11, wherein:
the field device is so embodied that it is suitable for use in an explosion endangered area.

13. The field device as claimed in claim 11, wherein:
said component space is embodied according to a first ignition protection type and said second component comprises a sensor module, or actuator module, embodied according to a second ignition protection type;
said sensor module, or said actuator module, is spaced from said component;
said sensor module, or said actuator module, includes, respectively, a sensor or an actuator;
said energy transmitting antenna is associated with said connector space; and
said energy receiving antenna is associated with said sensor module and said energy transmitting antenna supplies said sensor module, or said actuator module, wirelessly with energy.

14. The field device as claimed in claim 13, wherein:
said connector space is embodied pressure resistantly, especially such that it qualifies for Ex d ignition protection; and
said sensor module is embodied to be intrinsically safe, especially such that it qualifies for Ex i ignition protection.

15. The field device as claimed in claim 12, wherein:
communication between said connector space and said sensor module occurs with galvanic isolation, especially via radio or via fiber optics.

16. The field device as claimed in claim 11, wherein:
the field device is a radar measuring device for determining fill level of a fill substance in a container;
there is arranged in said connector space sensor electronics for processing/evaluating measurement data delivered by said sensor module; and
there is arranged in said sensor module an HF module for producing high-frequency measurement signals.

17. The field device as claimed in claim 11, wherein:
said second component other supplemental components are provided, which are supplied with energy either simultaneously via said energy transmitting antenna or in series via other transmission antennas present on said supplemental components.

18. The field device as claimed in claim 11, wherein:
a superordinated control unit is assigned to the field device; and
communication between the field device and said superordinated control unit occurs via at least one connecting line matched to the respective explosion endangered area.

19. The field device as claimed in claim 13, wherein:
there is provided in said sensor module an energy storer, which stores energy received by said energy receiving antenna.

20. The system as claimed in claim 18, wherein:
said superordinated control unit is a PLC, i.e. a programmable logic controller, or a PCS, i.e. a process control system.
